(19) United States
(12) Patent Application Publication
(10) Pub. No.: US 2025/0379148 A1
(43) Pub. Date: Dec. 11, 2025

(54) SEMICONDUCTOR DEVICE WITH SIDEWALL POWER CONNECTION TO BACKSIDE POWER DELIVERY NETWORK

(71) Applicant: INTERNATIONAL BUSINESS MACHINES CORPORATION, ARMONK, NY (US)

(72) Inventors: Manasa Medikonda, Albany, NY (US); Tao Li, Slingerlands, NY (US); Ruilong Xie, Niskayuna, NY (US); Joshua M. Rubin, Albany, NY (US)

(21) Appl. No.: 18/740,473

(22) Filed: Jun. 11, 2024

(51) Int. Cl. H01L 23/528; H01L 23/498

(52) U.S. Cl. CPC H01L 23/5286; H01L 23/49816; H01L 23/5283

(57) ABSTRACT

A semiconductor device includes a logic device, a backside power delivery network (BSPDN), and a power device electrically connecting the BSPDN to a package coupled to the semiconductor device. The power device includes a bottom power plate extended horizontally above the logic device, a top power plate extended horizontally above the bottom power plate, and a sidewall power track extended vertically from the top power plate to the package to electrically connect the BSPDN to the package. The sidewall power track at least partially wraps around a first edge of the semiconductor device.

### BACKGROUND

### Technical Field

The present disclosure generally relates to semiconductors, and more particularly, to semiconductors with sidewall connection to the backside power delivery network structure, and methods of creation thereof.

### Description of Related Art

The relentless miniaturization of transistors and their increasing density on chips epitomize the semiconductor industry's innovation, largely adhering to Moore's Law. This trend has led to transistors shrinking to nanometer scales, allowing millions and even billions to fit on a single chip, significantly enhancing computational power and energy efficiency. The evolution towards system-on-chip architectures integrates various functionalities, including processing and sensing, on one chip.

### SUMMARY

According to an embodiment, a semiconductor device includes a logic device, a backside power delivery network (BSPDN), and a power device electrically connecting the BSPDN to a package coupled to the semiconductor device. The power device includes a bottom power plate extended horizontally above the logic device, a top power plate extended horizontally above the bottom power plate, and a sidewall power track extended vertically from the top power plate to the package to electrically connect the BSPDN to the package. The sidewall power track at least partially wraps around a first edge of the semiconductor device.

In one embodiment, the semiconductor device includes one or more backside contacts connecting the logic device to the power device.

In one embodiment, the sidewall power track is connected to a backside of the logic device through the one or more backside contacts.

In one embodiment, at least one backside contact of the one or more backside contacts is isolated from direct contact with the top power plate via an insulation layer.

In one embodiment, the logic device further includes a back end of line (BEOL). The BEOL is connected to input/output ports of the package via one or more bumps.

In one embodiment, the logic device is connected to the package via an interconnect layer and the one or more bumps.

In one embodiment, the bottom plate is connected to the package via the one or more backside contacts and the one or more bumps.

According to an embodiment, a method for fabrication of a semiconductor device includes forming a logic device, forming a backside power delivery network (BSPDN) below the logic device, and establishing an electrical connection between the BSPDN and a package coupled to the semiconductor device via a power device. Establishing electrical connection between the BSPDN and the package includes forming a sidewall power track extended vertically from a top power plate to the package. The sidewall power track at least partially wraps around a first edge of the semiconductor device.

In one embodiment, establishing an electrical connection between the BSPDN and the package further includes forming a bottom power plate extended horizontally above the logic device, and forming the top power plate extended horizontally above the bottom power plate.

In one embodiment, the method includes establishing an electrical connection between the logic device and the power device via one or more backside contacts.

In one embodiment, the method includes connecting the sidewall power plate to a backside of the logic device through the one or more backside contacts.

In one embodiment, the method includes isolating at least one backside contact of the one or more backside contacts from direct contact with the top power plate via an insulation layer.

In one embodiment, the method includes forming a back end of line (BEOL) within the logic device, and establishing electrical connections between the BEOL and input/output ports of the package via one or more bumps.

According to an embodiment, a semiconductor device includes a logic device, a backside power delivery network (BSPDN), and a power device electrically connecting the BSPDN to a package coupled to the semiconductor device. The power device includes a top power plate extended horizontally below the logic device, a bottom power plate extended horizontally below the top power plate, and a sidewall power track extended vertically from the top power plate to the package to electrically connect the BSPDN to the package. The sidewall power track at least partially wraps around a first edge of the semiconductor device.

In one embodiment, the semiconductor device includes one or more backside contacts connecting the logic device to the power device.

In one embodiment, the sidewall power track is connected to a backside of the logic device through the one or more backside contacts.

In one embodiment, at least one backside contact of the one or more backside contacts is isolated from direct contact with the top power plate via an insulation layer.

In one embodiment, the logic device further comprises a back end of line (BEOL), wherein the BEOL is connected to input/output ports of the package via one or more bumps.

In one embodiment, the top power plate is connected to the package via the sidewall power track and the one or more bumps.

In one embodiment, the bottom power plate is connected to the package via the one or more bumps.

These and other features will become apparent from the following detailed description of illustrative embodiments thereof, which is to be read in connection with the accompanying drawings.

### BRIEF DESCRIPTION OF THE DRAWINGS

The drawings are of illustrative embodiments. They do not illustrate all embodiments.

Other embodiments may be used in addition or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIG. 1A illustrates a semiconductor device, in accordance with some embodiments.

FIG. 1B illustrates a top view of the semiconductor device depicted in FIG. 1A.

FIG. 2A illustrates a semiconductor device, in accordance with some embodiments.

FIG. 2B illustrates a top view of the semiconductor device depicted in FIG. 2A.

FIG. 3 illustrates a simplified cross-section view of a semiconductor device, after the front end of line (FEOL) formation and back end of line (BEOL) interconnect formation, consistent with an illustrative embodiment.

FIG. 4 illustrates the semiconductor device after the carrier wafer bonding, in accordance with some embodiments.

FIG. 5 illustrates the semiconductor device after the wafer flip, in accordance with some embodiments.

FIG. 6 illustrates the semiconductor device after the removal of the etch stop layer, in accordance with some embodiments.

FIG. 7 illustrates the semiconductor device after the formation of the backside interlayer dielectric, in accordance with some embodiments.

FIG. 8 illustrates the semiconductor device after the formation of the backside contacts for the top power plate, in accordance with some embodiments.

FIG. 9 illustrates the semiconductor device after the deposition of additional bottom interlayer dielectric and formation of the top power plate, in accordance with some embodiments.

FIG. 10 illustrates the semiconductor device after the deposition of additional bottom interlayer dielectric and formation of the via through the top power plate, in accordance with some embodiments.

FIG. 11 illustrates the semiconductor device after the formation of the backside contacts for the bottom power plate, in accordance with some embodiments.

FIG. 12 illustrates the semiconductor device after the deposition of additional bottom interlayer dielectric and formation of the bottom power plate, in accordance with some embodiments.

FIG. 13 illustrates the semiconductor device after the carrier wafer de-bonding on back end of line and carrier wafer bonding on the backside of the semiconductor device, in accordance with some embodiments.

FIG. 14A illustrates the semiconductor device after the dicing the semiconductor device, in accordance with some embodiments.

FIG. 14B illustrates a top view of the semiconductor device shown in FIG. 14A after dicing into chiplets.

FIG. 15A illustrates the semiconductor device after the deposition of dielectric and planarization, in accordance with some embodiments.

FIG. 15B illustrates a top view of the semiconductor device shown in FIG. 15A after filling with the dielectric layer 1510 and the planarization.

FIG. 16A illustrates the semiconductor device after the patterning of the sidewall metal trench, in accordance with some embodiments.

FIG. 16B illustrates a top view of the semiconductor device shown in FIG. 16A after patterning of the sidewall metal trench.

FIG. 17A illustrates the semiconductor device after the deposition of a seed layer over the sidewalls of the trench, in accordance with some embodiments.

FIG. 17B illustrates a top view of the semiconductor device shown in FIG. 17A after deposition of the seed layer over the sidewalls of the trench.

FIG. 18A illustrates the semiconductor device after the growth of the seed layer over the sidewalls of the trench, in accordance with some embodiments.

FIG. 18B illustrates a top view of the semiconductor device shown in FIG. 18A after the growth of the seed layer of the sidewalls of the trench.

FIG. 19A illustrates the semiconductor device after the recession of exposed copper and cap formation, in accordance with some embodiments.

FIG. 19B illustrates a top view of the semiconductor device shown in FIG. 19A after the recession of the exposed copper and the cap formation.

FIG. 20A illustrates the semiconductor device after the formation of the bumps, in accordance with some embodiments.

FIG. 20B illustrates a top view of the semiconductor device shown in FIG. 20A after the formation of the one or more bumps.

FIG. 21A illustrates the semiconductor device after the carrier wafer de-bonding and dicing the semiconductor device, in accordance with some embodiments.

FIG. 21B illustrates a top view of the semiconductor device shown in FIG. 21A after the carrier wafer de-bonding.

FIG. 22A illustrates the semiconductor device after the patterning of the sidewall metal trench, in accordance with some embodiments.

FIG. 22B illustrates a top view of the semiconductor device shown in FIG. 22A after patterning of the sidewall metal trench.

FIG. 23A illustrates the semiconductor device after the deposition of the copper layer over the sidewalls of the trench, in accordance with some embodiments.

FIG. 23B illustrates a top view of the semiconductor device shown in FIG. 23A after the deposition of the copper layer over the sidewalls of the trench.

FIG. 24A illustrates the semiconductor device after the formation of the bumps, in accordance with some embodiments.

FIG. 24B illustrates a top view of the semiconductor device shown in FIG. 24A after the formation of the one or more bumps.

FIG. 25A illustrates the semiconductor device after the carrier wafer de-bonding and dicing the semiconductor device, in accordance with some embodiments.

FIG. 25B illustrates a top view of the semiconductor device shown in FIG. 25A after the carrier wafer de-bonding and dicing the semiconductor device.

FIG. 26A illustrates the semiconductor device after the carrier wafer de-bonding and dicing the semiconductor device, in accordance with some embodiments.

FIG. 26B illustrates a top view of the semiconductor device shown in FIG. 26A after the carrier wafer de-bonding and dicing the semiconductor device

FIG. 27 illustrates a block diagram of a method for forming the semiconductor device, in accordance with some embodiments.

### DETAILED DESCRIPTION

### Overview

In the following detailed description, numerous specific details are set forth by way of examples to provide a thorough understanding of the relevant teachings. However, it should be apparent that the present teachings may be practiced without such details. In other instances, well-known methods, procedures, components, and/or circuitry have been described at a relatively high-level, without detail, to avoid unnecessarily obscuring aspects of the present teachings.

In one aspect, spatially related terminology such as “front,” “back,” “top,” “bottom,” “beneath,” “below,” “lower,” above,” “upper,” “side,” “left,” “right,” and the like, is used with reference to the orientation of the Figures being described. Since components of embodiments of the disclosure can be positioned in a number of different orientations, the directional terminology is used for purposes of illustration and is in no way limiting. Thus, it will be understood that the spatially relative terminology is intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as below. The device may be otherwise oriented (rotated 90 degrees or viewed or referenced at other orientations) and the spatially relative descriptors used herein should be interpreted accordingly.

As used herein, the terms “lateral” and “horizontal” describe an orientation parallel to a first surface of a chip.

As used herein, the term “vertical” describes an orientation that is arranged perpendicular to the first surface of a chip, chip carrier, or semiconductor body.

As used herein, the terms “coupled” and/or “electrically coupled” are not meant to mean that the elements must be directly coupled together-intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together.

Although the terms first, second, etc., may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used and structural or logical changes may be made without departing from the spirit and scope defined by the claims. The description of the embodiments is not limiting. In particular, elements of the embodiments described hereinafter may be combined with elements of different embodiments.

The concepts herein relate to semiconductors and their packaging. For the backside power delivery network (BSPDN) process in semiconductor packaging, which utilizes metal plates as power terminations, accessing the metal plates can be problematic. Using metal plates as power terminations also poses its own set of problems. Metal plates can introduce parasitic capacitance and inductance, affecting the overall electrical performance of the BSPDN. This can lead to signal integrity issues and increased power loss. Moreover, thermal management of metal plates can be challenging, as they can contribute to localized heating, potentially affecting the reliability and lifespan of the chiplets.

In view of the above considerations, disclosed is a semiconductor device with utilizing metal plates as power terminations, which can offer accessing the metal plates from the sidewall. The disclosed semiconductor device can leverage the spaces between chiplets for power wire patterning, which is particularly beneficial for mobile devices or small chiplet integration. By precise alignment, the metal plates can be accessed from the sidewall and incomplete or inefficient power delivery, which can compromise the performance of the entire chiplet system, can be avoided. Thus, the disclosed semiconductor device with sidewall access for BSPDN can enhance the efficiency and integration density of power delivery networks in semiconductor packaging. By addressing the alignment and thermal management issues and optimizing the use of metal plates, it is possible to achieve a more streamlined and effective power delivery solution, particularly suited for mobile and small chiplet systems.

Accordingly, the teachings herein provide methods and systems of semiconductor device formation with sidewall power connection to the BSPDN. The techniques described herein may be implemented in a number of ways. Example implementations are provided below with reference to the following figures.

Example Semiconductor Device with Sidewall Power Connection to BSPDN Structure

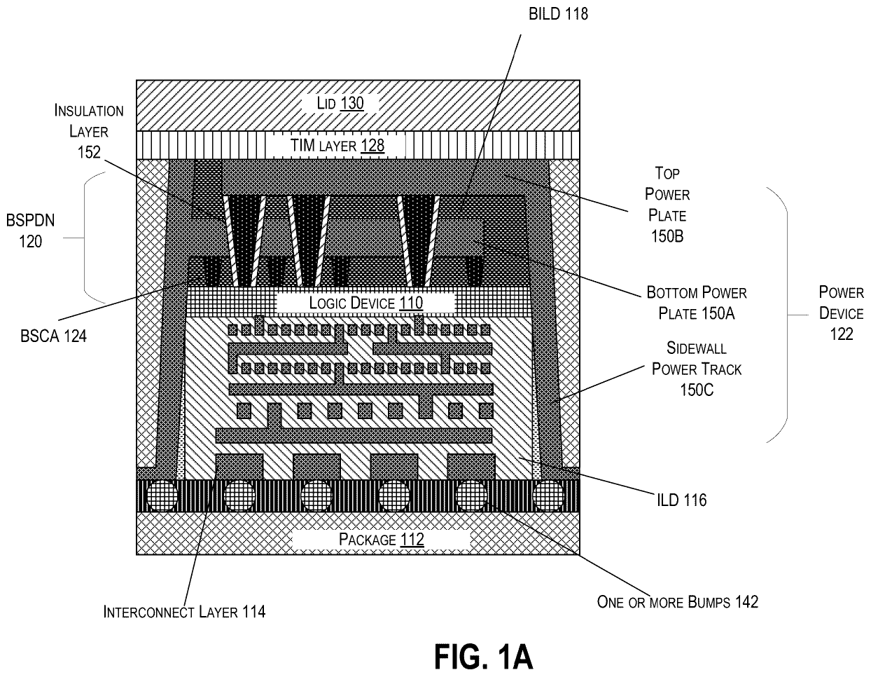

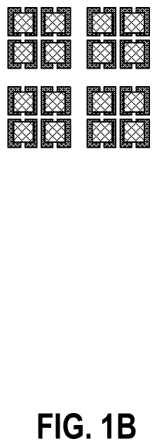

Reference now is made to FIG. 1A, which is a simplified cross-section view of a semiconductor device, consistent with an illustrative embodiment. FIG. 1B illustrates a top view of the semiconductor device depicted in FIG. 1A. In various embodiments, the semiconductor device includes a logic device 110, a package 112, an interconnect layer 114, an interlayer dielectric, ILD 116, a bottom ILD, BILD 118, a backside power delivery network, BSPDN 120, backside contacts, BSCA 124, a thermal interface material layer, TIM layer 128, and a lid 130.

The logic device 110 can be an electronic device to perform logical operations on binary inputs to produce a binary output. In some embodiments, the logic device 110 can be a transistor. In some embodiments, the logic device 110 can be logic gates to perform simple logical functions such as AND, OR, NOT, NAND, NOR, XOR, and XNOR. Each gate type can perform a specific logical operation on its inputs to produce an output. For example, an AND gate outputs a high signal only when all its inputs are high, while an OR gate outputs a high signal if at least one of its inputs is high. In an embodiment, the logic device 110 can be flip-flops which are bistable devices used for storing binary data. A flip-flop can exist in one of two stable states, representing a binary 0 or 1. As a non-limiting example, the logic device 110 can be set-reset, data or delay, and toggle flip-flops. In some embodiments, the logic device 110 can be multiplexers (MUX) that select one of several input signals and forward the selected input to a single output line, and can function as multi-input, single-output switches controlled by additional selection inputs. In another embodiment, the logic device 110 can be demultiplexers (DEMUX) to perform the inverse operation of a multiplexer, in which the DEMUX takes a single input signal and distributes it to one of several output lines, determined by selection inputs.

In some embodiments, the logic device 110 can be decoders to convert binary information from n input lines to a maximum of 2\hat{ }n unique output lines. Similarly, the logic device 110 can be encoders to perform the reverse operation of a decoder by converting information from 2\hat{ }n input lines to n output lines, effectively compressing multiple input signals into fewer output signals. The logic device 110 can further include programmable logic devices (PLDs) which can be programmed to perform a wide variety of logical operations. For example, the logic device 110 can include programmable array logic (PAL), generic array logic (GAL), and field-programmable gate arrays (FPGA).

In some embodiments, the logic device 110 can include a back end of line, BEOL 140. the BEOL 140 can be connected to a package 112 via one or more bumps 142. In an embodiment, the BEOL 140 can be connected to the input/output ports of the package 112. In some embodiments, the logic device 110 can be connected to the package 112 via the interconnect layer 114 and the one or more bumps 142.

The package 112 can be a protective housing that encases the semiconductor device, and can provide physical and/or electrical connections between the semiconductor device and the external environment, such as a printed circuit board (PCB). The package 112 can protect the semiconductor device from mechanical damage and moisture, aid in dissipating heat generated by the semiconductor device during operation, and provide a means to connect the internal circuitry of the semiconductor device to the external pins or leads, enabling integration with other electronic components on a PCB. Additionally, the package 112 can offer structural support for the semiconductor device, ensuring reliable and stable mounting onto the PCB. In some embodiments, the package 112 can be dual in-line package (DIP), surface mount device (SMD) package such as quad flat package (QFP) and ball grid arrays (BGA), and advanced packages such as chip-scale package (CSP) and wafer-level package (WLP).

The interconnect layer 114 can be a layer of metal to serve as the foundational layer for routing electrical connections within the device. The interconnect layer 114 can establish horizontal and vertical interconnections between transistors and other components on the semiconductor device, and allow for densely packed circuitry.

ILD 116 can be a layer of insulating material to electrically isolate and provide mechanical support between different layers of conducting and active components. The ILD 116 can enable efficient signal transmission, reduce crosstalk, and ensure the proper functioning of the semiconductor device. In an embodiment, the ILD 116 can electrically isolate adjacent conducting layers or active components in the semiconductor device. By providing insulation between different layers, the ILD 116 can prevent electrical shorts, reduce (e.g., minimize) leakage current, and ensure that signals are directed only along the desired pathways. In some embodiments, the ILD 116 can help reduce parasitic capacitance between adjacent metal interconnects or active devices and provide mechanical support to the semiconductor device's structure.

In several embodiments, the BILD 118 can provide structural support to the semiconductor device by maintaining the mechanical integrity and stability of the semiconductor device. The BILD 118 can further help prevent the warping, bending, or cracking of the substrate, particularly during the manufacturing process or subsequent handling. The BILD 118 can ensure that the semiconductor device remains mechanically robust and maintains its dimensional stability.

In an embodiment, the BILD 118 can also serve as a planarization layer in the semiconductor device fabrication process. As various layers are deposited and patterned on the front side of the semiconductor device, irregularities or topographic variations may arise. The BILD 118 can be used to smoothen the surface, creating a more planar substrate for subsequent processing steps, such as metal interconnect deposition or bonding. In some embodiments, a low dielectric constant BILD material can be utilized to reduce signal delays, crosstalk, and power consumption in high-speed and high-frequency circuits. By optimizing the dielectric constant, the BILD 118 can contribute to improved overall semiconductor device performance. In several embodiments, BILD 118 can facilitate wafer-level testing of the semiconductor device. By providing electrical isolation between the active regions and the backside contact, individual passive device or elements on the semiconductor device can be electrically accessed and tested without interference from neighboring devices or components. This enables efficient and accurate wafer-level testing, ensuring quality control during semiconductor manufacturing.

BSPDN 120 can reduce the voltage drop across the power delivery network by delivering power through the backside, leading to a more stable and reliable power supply to the logic device and enhancing the overall performance of the semiconductor device. In some embodiments, by offloading power delivery to the backside, the front-side metal layers can be dedicated to signal routing, reducing congestion and improving signal integrity by minimizing crosstalk and electromagnetic interference. BSPDN 120 can enhance thermal management by providing an additional path for heat dissipation, with the backside metal layer acting as a heat spreader, thereby improving the overall thermal performance of the semiconductor device.

In some embodiments, the semiconductor device can include a power device 122 which can electrically connect the BSPDN 120 to the package 112. The power device 122 can include a bottom power plate 150A, a top power plate 150B, and a sidewall power track 150C. The bottom power plate 150A can be extended horizontally above the logic device 110. The top power plate 150B can be extended horizontally above the bottom power plate 150A. The sidewall power track 150C can be extended vertically from the top power plate 150B to the package 112 to electrically connect the BSPDN 120 to the package 112.

In some embodiments, the sidewall power track 150C can at least partially wrap around a first edge of the semiconductor device. The sidewall power track 150C can be connected to a backside of the logic device 110 through the BSCA 124. The top power plate 150B can be connected to the package 112 via the BSCA 124 and the one or more bumps 142.

The BSCA 124 connects the bottom power plate 150A and the top power plate 150B to the logic device 110. The BSCA 124 can be a region on the backside of the semiconductor device where electrical connections are made. By establishing the electrical contacts, the BSCA 124 can ensure the proper functioning of the semiconductor device and facilitates electrical signal transmission. The BSCA 124 can serve as a thermal interface between the semiconductor device and a heat sink or other cooling mechanisms. In some embodiments, the BSCA 124 can help mitigate parasitic effects, such as substrate coupling or substrate noise, from the semiconductor device. In further embodiments, the BSCA 124 can allow for increased integration density in the semiconductor device. In an embodiment, the BSCA 124 can serve as means of providing electrostatic discharge protection to the semiconductor device. Electrostatic discharge events can cause significant damage to sensitive electronic components and thus should be avoided.

In some embodiments, the BSCA 124 can connect the logic device 110 to the power device 122. In some embodiments, at least one BSCA can be isolated from direct contact with the top power plate 150B via an insulation layer 152.

In some embodiments, the top power plate 150B and the bottom power plate 150A can act as negative supply voltage and/or positive supply voltage, VSS/VDD, respectively. The VSS/VDD can be power supply voltages within the semiconductor device. VSS/VDD can define the operating voltage range for the semiconductor device. The difference between VDD and VSS (VDD−VSS) can be the supply voltage that powers the semiconductor device. The VSS can be the ground or zero voltage reference point in the circuit, and represent the lower potential end of the power supply. The VSS can be connected to the ground plane of the logic device 110. The VDD can be the positive supply voltage, and represent the higher potential end of the power supply. In some embodiments, the VDD is the voltage provided to the drain terminal of the logic device 110. The VDD can be the power source for the circuit and determine the operating voltage for the components within the semiconductor device.

In some embodiments, the TIM layer 128 is placed between a heat-generating component, i.e., the semiconductor device, and a heat sink or other cooling solution, to improve thermal conductivity between these surfaces, ensuring efficient heat transfer and preventing the semiconductor device from overheating.

In some embodiments, the TIM layer 128 can fill microscopic air gaps and irregularities on the surfaces of the semiconductor device and the heat sink, which can otherwise impede heat transfer due to air's poor thermal conductivity. The TIM layer 128 can be made of thermally conductive materials, such as thermal greases, thermal pads, phase-change materials, or liquid metal. In an am embodiment, the TIM layer 128 has a high thermal conductivity and a low thermal resistance, which facilitates efficient heat transfer and maintains the semiconductor device's operating temperature within safe limits.

The lid 130 can be made of materials such as metal or ceramic and can provide a protective enclosure for the semiconductor device and the TIM layer 128, shielding them from physical damage, contaminants, and environmental factors such as moisture and dust. In some embodiments, the lid 130 can help to ensure efficient heat transfer from the semiconductor device to the heat sink or other cooling solutions. The lid 130 can provide mechanical support and structural integrity to the semiconductor device, and help maintain the alignment and positioning of the semiconductor device, ensuring stable and reliable connections.

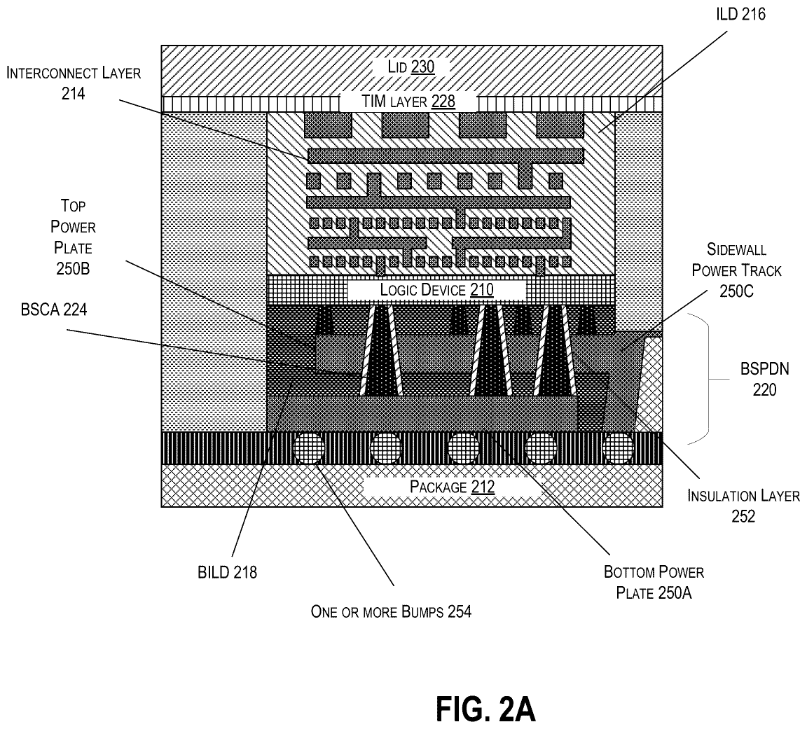

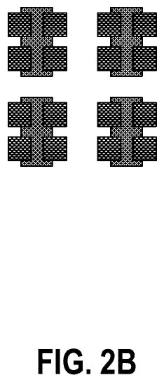

Reference now is made to FIG. 2A, which is a simplified cross-section view of a semiconductor device, consistent with an illustrative embodiment. FIG. 2B illustrates a top view of the semiconductor device depicted in FIG. 2A. The semiconductor device shown in FIG. 2A can be different from the semiconductor device shown in FIG. 1A, since the logic device 210 is located below the ILD 216, instead of above the ILD 116. In various embodiments, the semiconductor device includes the logic device 210, a package 212, an interconnect layer 214, ILD 216, BILD 218, BSPDN 220, BSCA 224, a TIM Layer 228, and a lid 230.

The power device, similar to the power device 122, can include a top power plate 250A extended horizontally below the logic device 210, a bottom power plate 250B extended horizontally below the top power plate 250A, and a sidewall power track 250C extended vertically from the top power plate 250A to the package 212 to electrically connect the BSPDN 220 to the package 212. The sidewall power track 250C can at least partially wrap around a first edge of the semiconductor device. For the sake of simplicity, the power device is only shown in FIG. 1A, and the components of the power device are shown in FIGS. 2-26.

In some embodiments, the sidewall power track 250C is connected to a backside of the logic device 250 through the BSCA 224, and at least one backside contact of the BSCA 224 is isolated from direct contact with the top power plate 250A via an insulation layer 252. The top power plate 250A can be connected to the package 212 via the sidewall power track 250C and one or more bumps 254. In an embodiment, the bottom power plate 250B can be connected to the package 212 via the one or more bumps 254.

Example Fabrication of a Semiconductor Device with Sidewall Power Connection to BSPDN Substrate

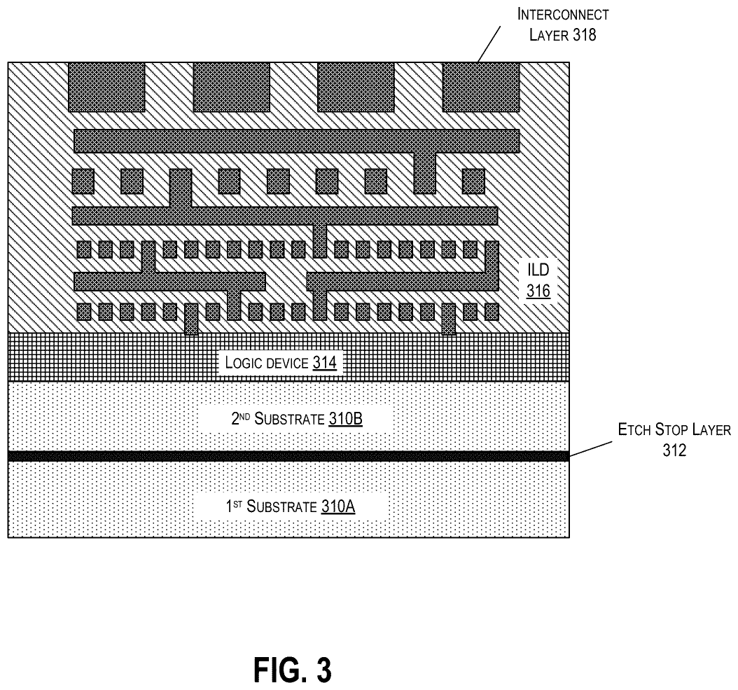

With the foregoing description of an example semiconductor device, it may be helpful to discuss an example process of manufacturing the same. To that end, FIGS. 3-26 illustrate various acts in the manufacture of a semiconductor device, consistent with illustrative embodiments. FIGS. 3-26 depict acts of fabrication of the semiconductor device. Figures denoted by A show the acts of fabrication of the semiconductor device in a cross-section, and figures denoted by B illustrate a top view of the semiconductor device.

Reference now is made to FIGS. 3-21, which show the acts of fabrication of the semiconductor device as shown in FIG. 1A. FIG. 3 illustrates a simplified cross-section view of a semiconductor device, after the front end of line (FEOL) formation and back end of line (BEOL) interconnect formation, consistent with an illustrative embodiment. The semiconductor device 300A can include a first substrate 310A, a second substrate 310B, an etch stop layer 312, a logic device 314, an ILD 316, and an interconnect layer 318.

In the illustrative example depicted in FIG. 3, the semiconductor device is depicted as being on silicon as the first substrate 310A and the second substrate 310B, while it will be understood that other types as the first substrate 310A and the second substrate 310B can be used as well, including, without limitation, monocrystalline Si, silicon germanium (SiGe), III-V compound semiconductor, II-VI compound semiconductor, or semiconductor-on-insulator (SOI). Group III-V compound semiconductors, for example, include materials having at least one group III element and at least one group V element, such as one or more of aluminum gallium arsenide (AlGaAs), aluminum gallium nitride (AlGaN), aluminum arsenide (AlAs), aluminum indium arsenide (AlIAs), aluminum nitride (AlN), gallium antimonide (GaSb), gallium aluminum antimonide (GaAlSb), gallium arsenide (GaAs), gallium arsenide antimonide (GaAsSb), gallium nitride (GaN), indium antimonide (InSb), indium arsenide (InAs), indium gallium arsenide (InGaAs), indium gallium arsenide phosphide (InGaAsP), indium gallium nitride (InGaN), indium nitride (InN), indium phosphide (InP) and alloy combinations including at least one of the foregoing materials. The alloy combinations can include binary (two elements, e.g., gallium (III) arsenide (GaAs)), ternary (three elements, e.g., InGaAs), and quaternary (four elements, e.g., aluminum gallium indium phosphide (AlInGaP)) alloys.

In various embodiments, the first substrate 310A and the second substrate 310B can include any suitable material or combination of materials, such as doped or undoped silicon, glass, dielectrics, etc. For example, the substrate may include a silicon-on-insulator (SOI) structure, e.g., with a buried insulator layer, or a bulk material substrate, e.g., with appropriately doped regions, typically referred to as wells. In another embodiment, the substrate may be silicon with silicon oxide, nitride, or any other insulating film on top.

In various embodiments, the etch stop layer 312 is formed between the first substrate 310A and the second substrate 310B. The etch stop layer 312 can be a thin layer of material incorporated into the structure of the semiconductor device to provide a selective barrier against etching processes, preventing further removal of underlying materials during fabrication. The etch stop layer 312 can enable precise control over the etching depth and help define the desired device dimensions. The etch stop layer 312 can further provide a stopping point for the etching process, ensuring that specific layers or regions are not etched beyond a certain point, leading to accurate patterning and control of critical features.

The etch stop layer 312 can create a distinct separation between different layers or components within the device structure, and prevent the undesired etching of underlying layers or materials, enabling the creation of complex, multi-layered structures with well-defined interfaces and boundaries. In some embodiments, the etch stop layer 312 acts as a protective barrier for sensitive or delicate materials to shield such materials from aggressive etchants, preventing damage or degradation during subsequent fabrication steps.

In some embodiments, prior to forming the etch stop layer 312, the first substrate 310A and/or the second substrate 310B is prepared by cleaning and removing any impurities or oxide layers. The etch stop layer 312 is deposited onto the first substrate 310A using techniques such as chemical vapor deposition (CVD), physical vapor deposition (PVD), or atomic layer deposition (ALD). In an embodiment, a photoresist can be applied, exposed to a patterned mask, developed, and used as a protective layer to define the etch stop regions. The etch stop layer 312 can then be selectively etched, stopping at a predetermined depth, while protecting the underlying layers. After the etching process, the remaining photoresist can be removed through stripping techniques. While in some embodiments, SiGe is used to form the etch stop layer 312, in some embodiments, silicon nitride (SiN), silicon oxide (SiO2), or silicon oxynitride (SiON) can be used as the etch stop layer 312.

Interconnect layer 318 formation can involve creating the network of electrical connections that link various components within the semiconductor device. The process can begin with the deposition of a metal layer, such as aluminum and copper, on the wafer's surface. The metal can be deposited using techniques such as PVD or CVD. Following deposition, a photolithography process can be used to define the pattern of the interconnects, which involves coating the wafer with a photoresist, exposing it to ultraviolet light through a mask that defines the desired pattern, and then developing the exposed photoresist to reveal the metal underneath. The unwanted metal can be etched away, leaving behind the intricate network of interconnects. Etching can be performed using wet chemical processes or dry plasma etching. This results in the formation of the interconnect layer 318. In some embodiments, to insulate and protect these interconnect layer 318, an ILD 316 is applied.

The ILD 316 can be a layer of insulating material, such as silicon dioxide (SiO2) or low-k dielectrics, which provides electrical insulation between different layers of metal interconnects. The ILD 316 can be deposited using techniques such as plasma-enhanced chemical vapor deposition (PECVD) or spin-on deposition. After the ILD 316 is formed, vias or holes can be etched through the ILD 316 to allow connections between different layers of interconnects. Such vias can be then filled with a conductive material, such as tungsten or copper, to create vertical interconnections between the metal layers. The process of depositing metal, patterning, etching, applying ILD 316, and creating vias can be repeated multiple times to build up the complex multi-layer interconnect structure required for the semiconductor device.

In some embodiments, the interconnect layer 318 is encapsulated by the ILD 316. Encapsulation by the ILD 316 can insulate the interconnect layer 318 to prevent short circuits, provides mechanical support, and protect the interconnect layer 318 from environmental damage and contamination.

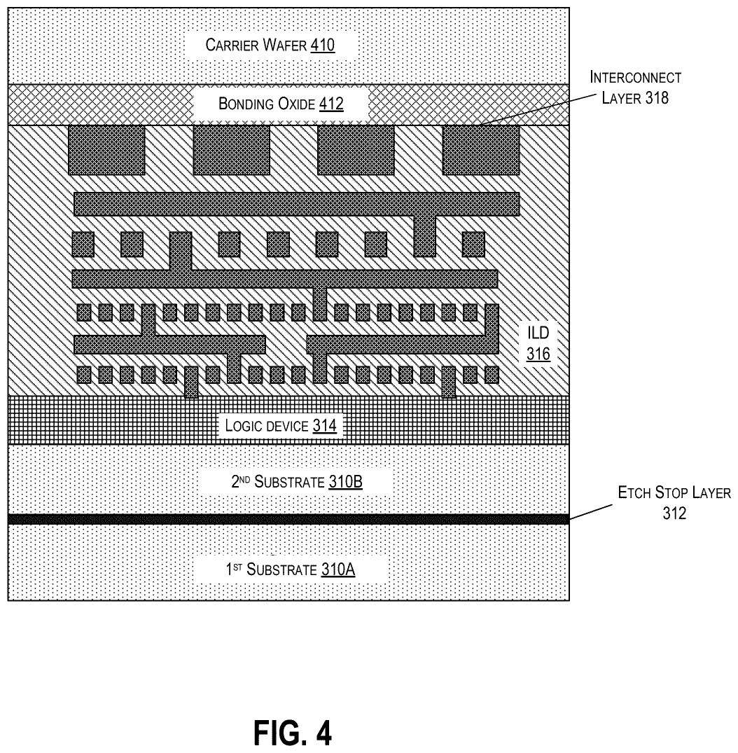

FIG. 4 illustrates the semiconductor device after the carrier wafer bonding, in accordance with some embodiments. In some embodiments, carrier wafer bonding, also known as wafer-to-wafer bonding or chip-to-wafer bonding, is performed to join two semiconductor devices together by creating a permanent bond between them. The carrier wafer 410 can be bonded to the semiconductor device via a bonding oxide 412. In some embodiments, the two semiconductor devices can be brought into contact and bonded at the atomic or molecular level, to create an interface. In an embodiment, the two semiconductor devices are brought into contact under controlled conditions, such as controlled pressure and temperature, to enable atomic or molecular bonding at the interface. Such bonding can be done at room temperature or with elevated temperatures. Alternatively, in some embodiments, an electric field and elevated temperature are utilized to create a bond. One semiconductor device can be made of semiconductor material, while the other can be a glass or silicon dioxide (SiO2) wafer.

The electric field can cause ions in the glass or SiO2 to migrate and chemically bond with the semiconductor material in the other semiconductor device. In additional embodiments, a thin metal layer or metal alloy can be used as an intermediate bonding layer between the semiconductor devices. The metal layer can be deposited or transferred onto one or both semiconductor device surfaces, and the semiconductor devices can then be brought into contact and subjected to temperature and pressure to create a metallic bond.

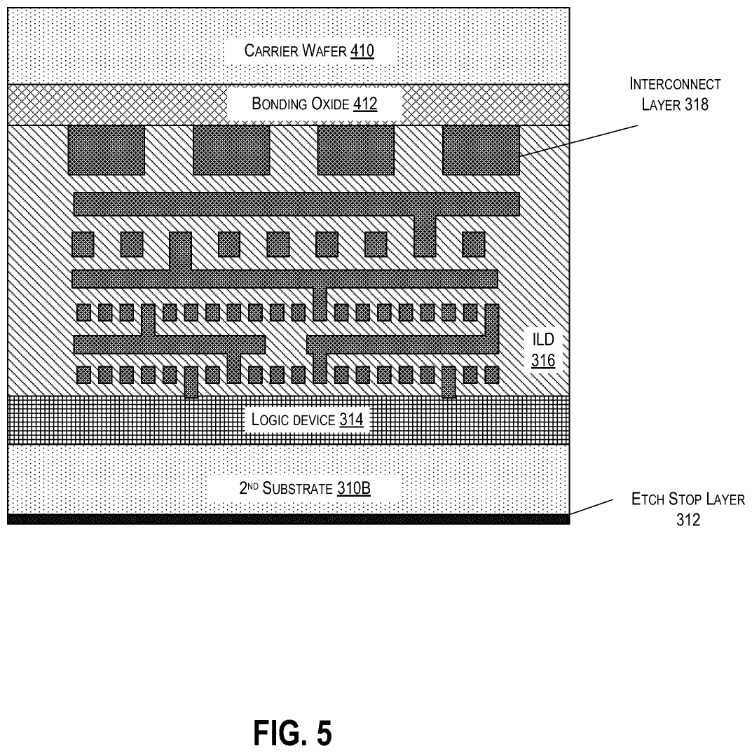

FIG. 5 illustrates the semiconductor device after the wafer flip, in accordance with some embodiments. In some embodiments, the wafer is flipped and the first substrate is removed from the semiconductor device. It should be noted that, for the sake of simplicity, the semiconductor device is not shown as flipped. In some embodiments, after the first substrate is removed, the etch stop layer 312 is exposed.

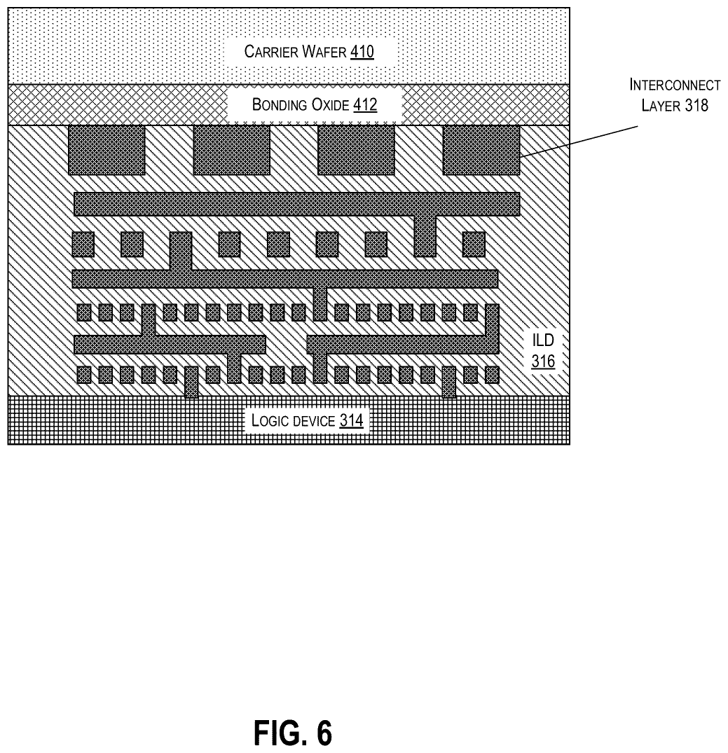

FIG. 6 illustrates the semiconductor device after the removal of the etch stop layer, in accordance with some embodiments. In some embodiments, the etch stop layer is removed and the second substrate 310B is exposed in the semiconductor device. The second substrate can be removed and the bottom surface of the logic device 314 can be exposed.

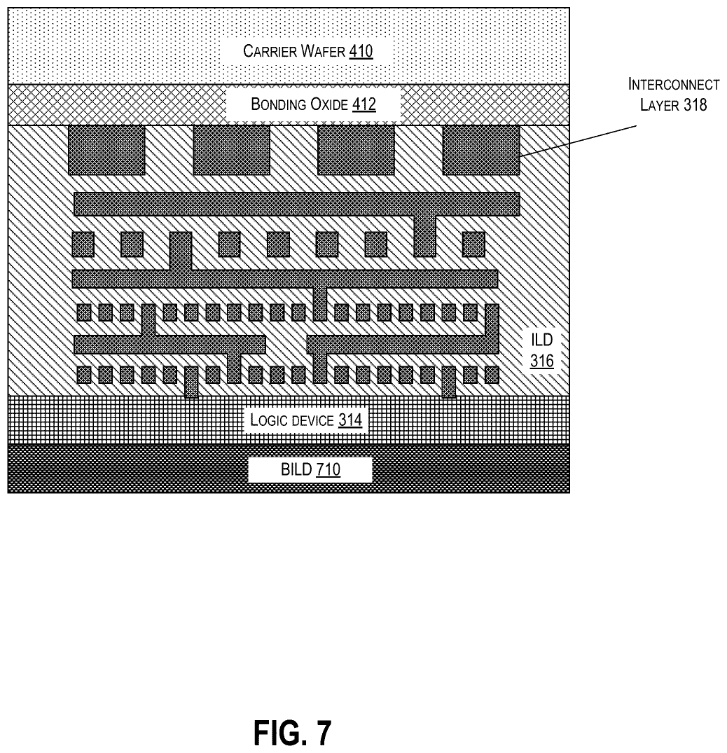

FIG. 7 illustrates the semiconductor device after the formation of the backside interlayer dielectric, in accordance with some embodiments. In some embodiments, the BILD 710 is formed over the logic device 314. The BILD 710 can be an insulating material or layer used to isolate and provide electrical insulation between the device's active regions and other components, and to prevent unwanted electrical contact between the active regions and the other components. In various embodiments, the BILD 710 can act as a protective layer, shielding the active regions of the semiconductor device from external contaminants, moisture, and mechanical stress. The BILD 710 can further help prevent physical damage, such as scratches or particle contamination, which could adversely affect semiconductor device performance. Additionally, the BILD 710 can act as a barrier against moisture ingress, which can cause corrosion and degradation of the semiconductor device's components.

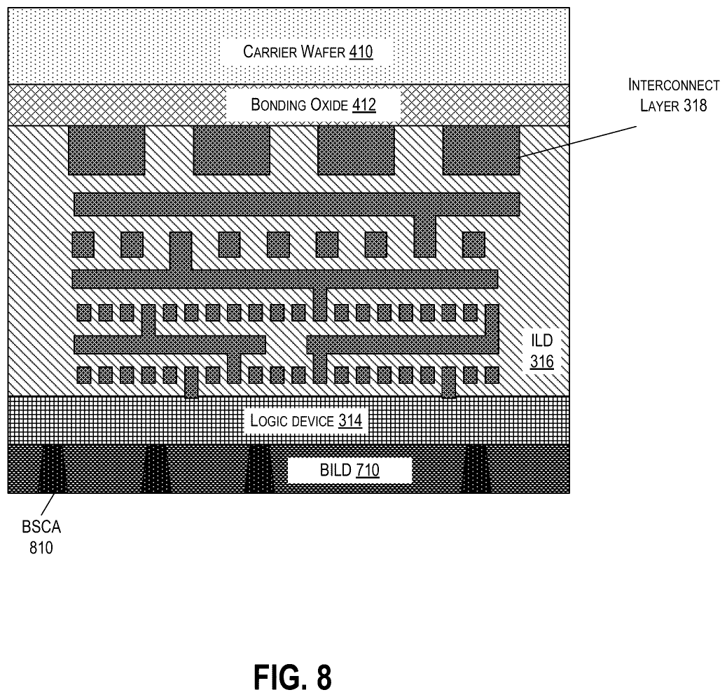

FIG. 8 illustrates the semiconductor device after the formation of the backside contacts for the top power plate, in accordance with some embodiments. In some embodiments, the backside of the semiconductor device is patterned by removing portions of the BILD 710, and exposing the logic device 314. The BSCA 810 is formed by filling the patterned portions of the BILD 710 with a suitable metal.

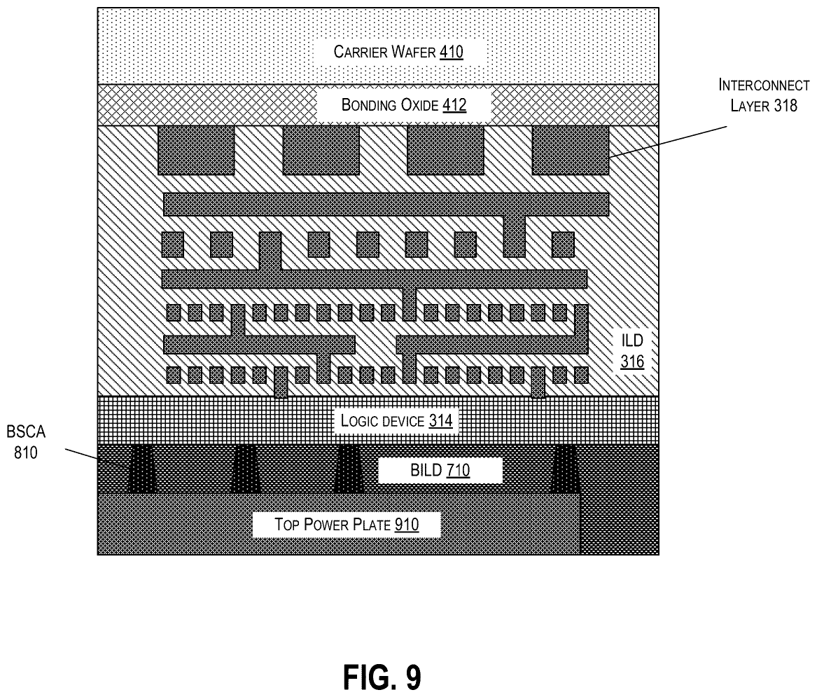

FIG. 9 illustrates the semiconductor device after the deposition of additional bottom interlayer dielectric and formation of the top power plate, in accordance with some embodiments. In some embodiments, a top power plate 910 is formed over portions of the BILD 710. The top power plate 910 is connected to the logic device 314 by the BSCA 810. A first additional layer of BILD 710 is deposited over portions of the semiconductor device that are not covered by the top power plate 910.

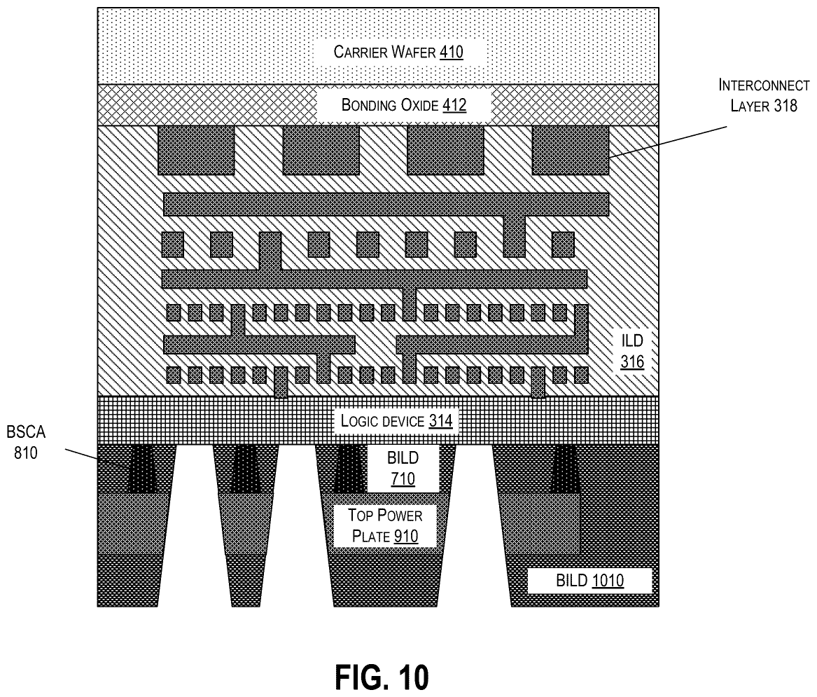

FIG. 10 illustrates the semiconductor device after the deposition of additional bottom interlayer dielectric and formation of the via through the top power plate, in accordance with some embodiments. In some embodiments, a second additional layer of BILD 1010 is formed over the semiconductor device, followed by recessing portions of the second additional layer of BILD 1010, the top power plate 910, and the BILD 710, to expose the bottom surface of the logic device 314.

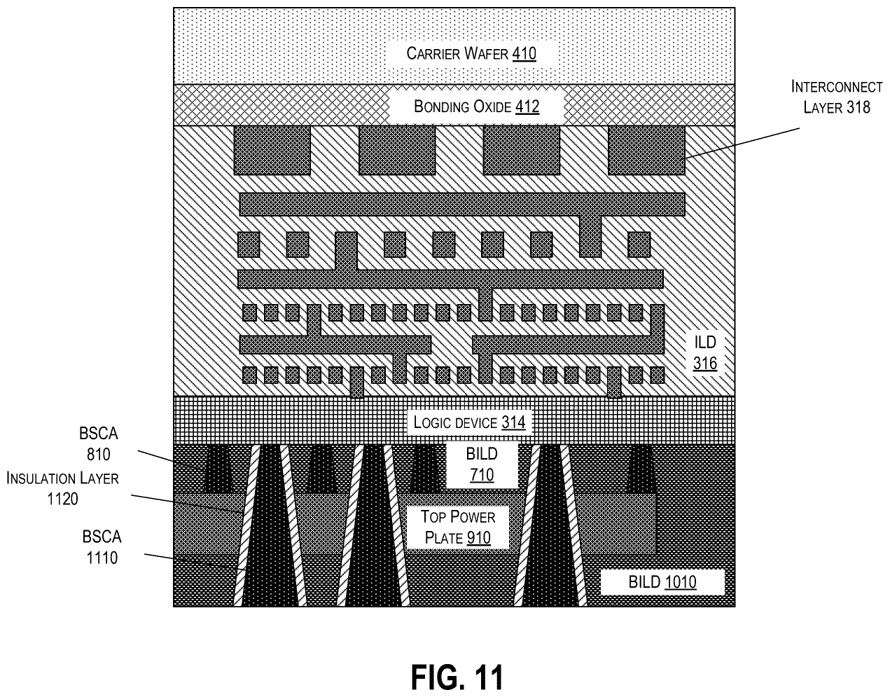

FIG. 11 illustrates the semiconductor device after the formation of the backside contacts for the bottom power plate, in accordance with some embodiments. In some embodiments, the BSCA 1110 is formed by filling the recessed portions of the second additional layer of BILD 1010, the top power plate 910, and the BILD 710, by a suitable metal. Prior to the formation of the BSCA 1110, an isolation layer 1120 can be deposited over the sidewalls of the recessed portions of the second additional layer of BILD 1010, the top power plate 910, and the BILD 710, to avoid the BSCA 1110 from direct contact with the second additional layer of BILD 1010, the top power plate 910, and the BILD 710.

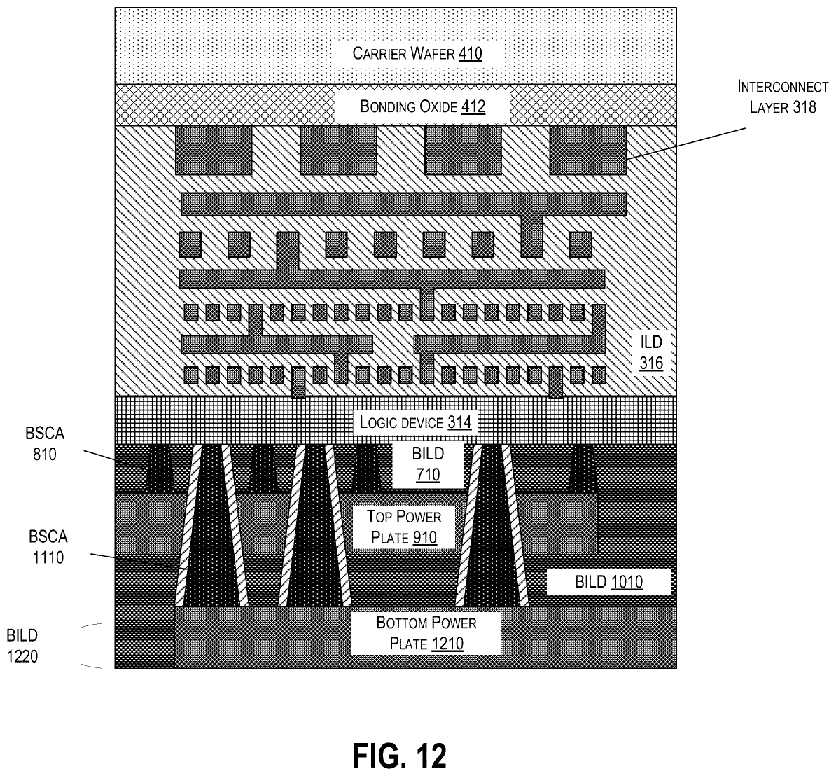

FIG. 12 illustrates the semiconductor device after the deposition of additional bottom interlayer dielectric and formation of the bottom power plate, in accordance with some embodiments. In some embodiments, a bottom power plate 1210 is formed over portions of the second additional layer of BILD 1010. The bottom power plate 1210 is connected to the logic device 314 by the BSCA 1110. A third additional layer of BILD 1220 is deposited over portions of the semiconductor device that are not covered by the bottom power plate 1210.

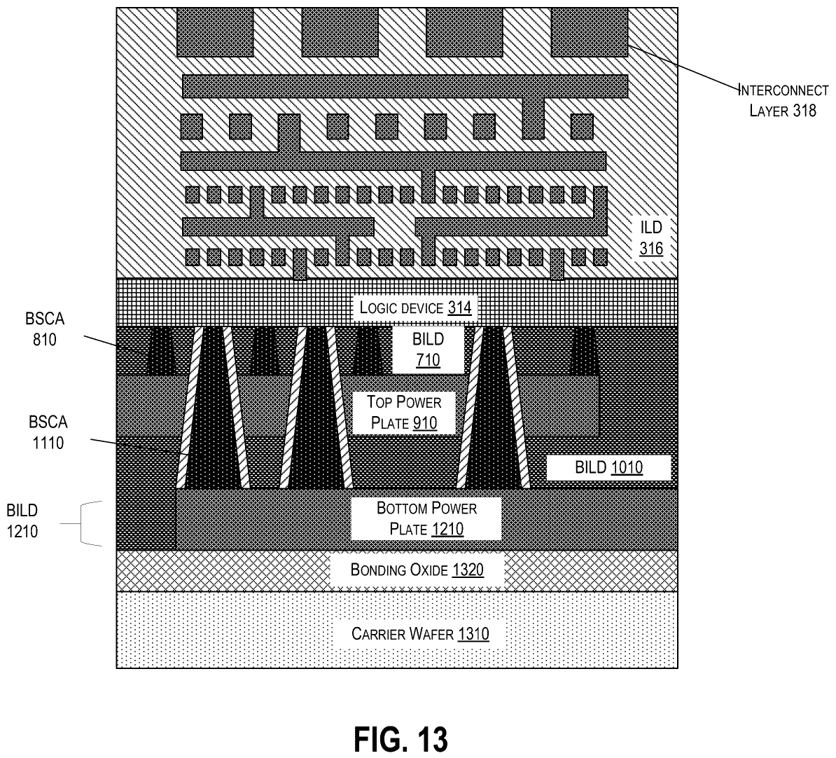

FIG. 13 illustrates the semiconductor device after the carrier wafer de-bonding on back end of line and carrier wafer bonding on the backside of the semiconductor device, in accordance with some embodiments. In some embodiments, the carrier wafer 410 and the bonding oxide 412 are de-bonded. A carrier wafer 1310 can be bonded to the semiconductor device via a bonding oxide 1320 on the backside of the semiconductor device.

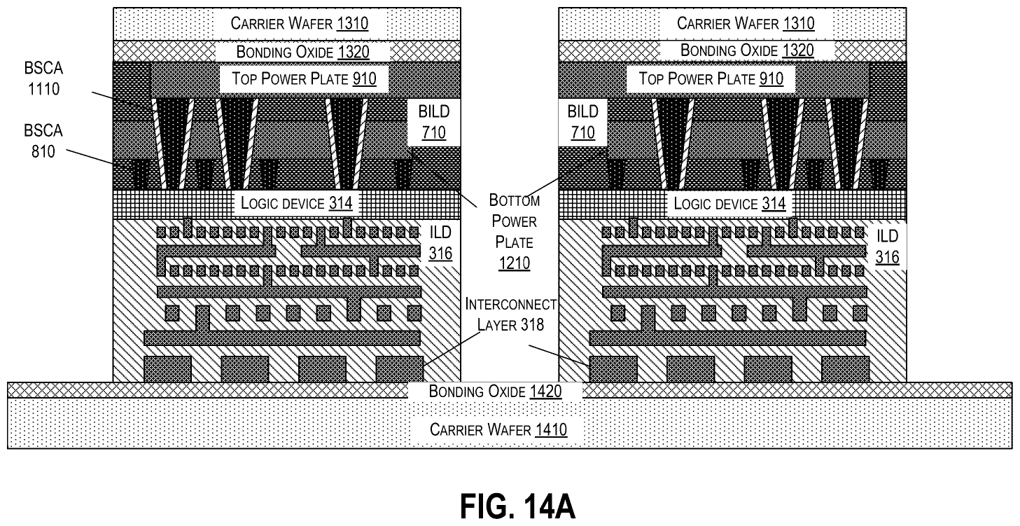

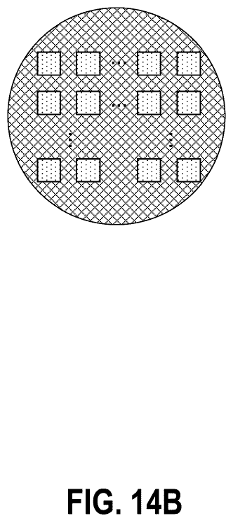

FIG. 14A illustrates the semiconductor device after the dicing the semiconductor device, in accordance with some embodiments. In some embodiments, the semiconductor device is diced into chiplets. The crack stop can be kept and the chiplets can be attached to a common carrier wafer, e.g., the carrier wafer 1310. A carrier wafer 1410 can be bonded to the semiconductor device via a bonding oxide 1420. As a result, the semiconductor device is bonded to the carrier wafer 1310 and carrier wafer 1410 on both sides. FIG. 14B illustrates a top view of the semiconductor device shown in FIG. 14A after dicing into chiplets.

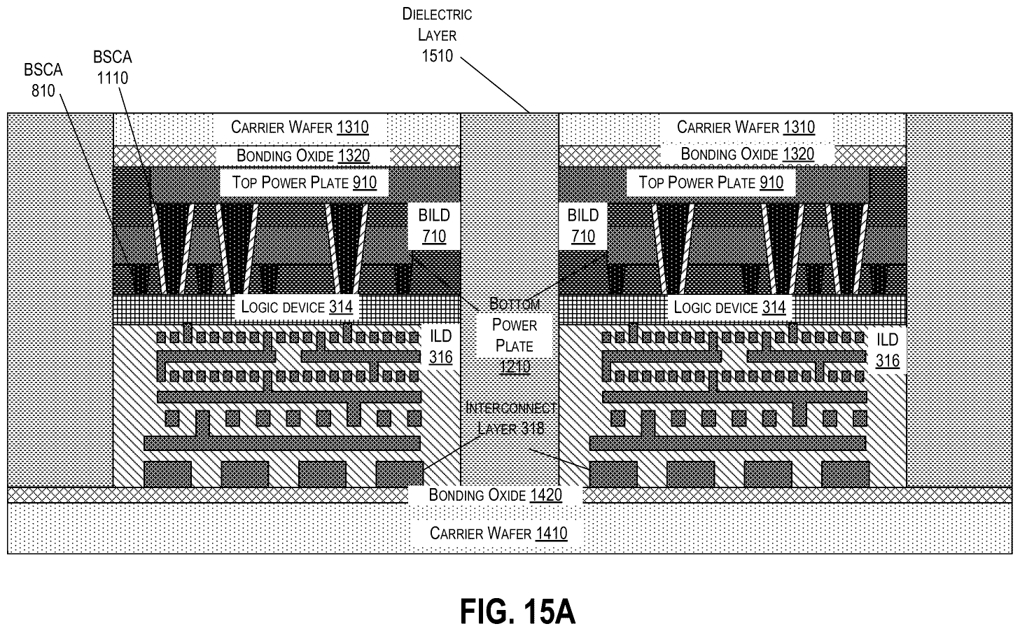

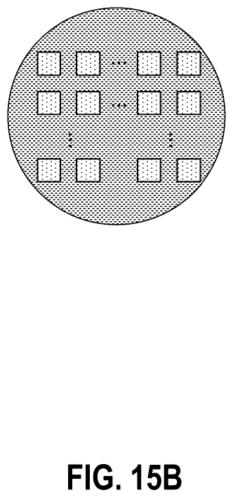

FIG. 15A illustrates the semiconductor device after the deposition of dielectric and planarization, in accordance with some embodiments. In some embodiments, a dielectric layer 1510 is deposited over the diced semiconductor device. A chemical-mechanical polishing (CMP), which involves the planarization of the semiconductor device's surface after each layer deposition, can be performed to ensure a flat and smooth surface for subsequent layers. FIG. 15B illustrates a top view of the semiconductor device shown in FIG. 15A after filling with the dielectric layer 1510 and the planarization.

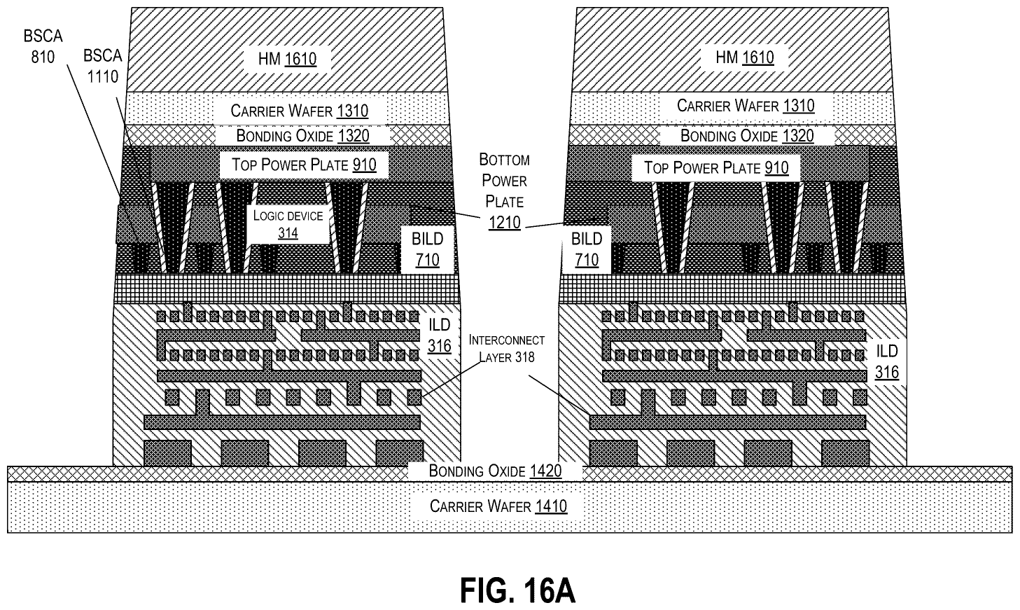

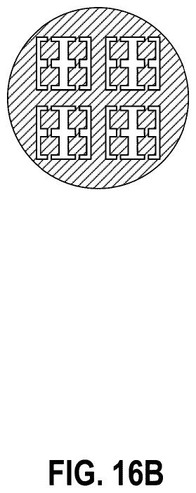

FIG. 16A illustrates the semiconductor device after the patterning of the sidewall metal trench, in accordance with some embodiments. In some embodiments, a hard mask, HM 1610 is formed over the carrier wafer 1410 of each chiplets of the diced semiconductor device. The dielectric layer 1510 can be removed. FIG. 16B illustrates a top view of the semiconductor device shown in FIG. 16A after patterning of the sidewall metal trench.

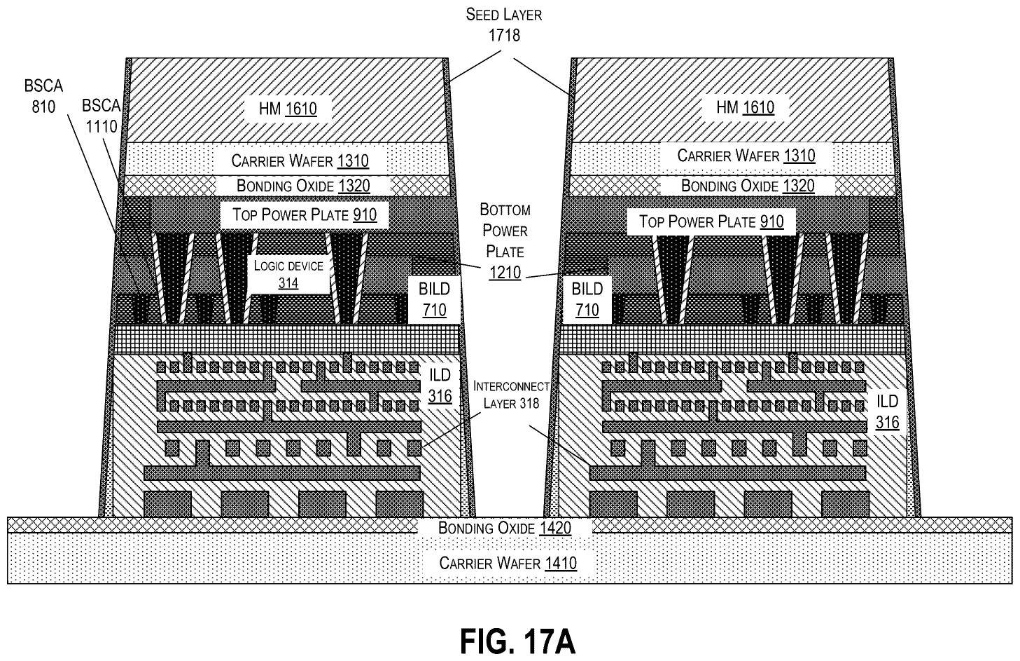

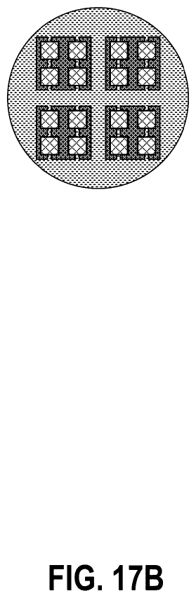

FIG. 17A illustrates the semiconductor device after the deposition of a seed layer over the sidewalls of the trench, in accordance with some embodiments. In some embodiments, a copper plating is performed to form a seed layer 1718 over the sidewalls of the trench. The seed layer 1718 can be formed by an electroless copper plating method. FIG. 17B illustrates a top view of the semiconductor device shown in FIG. 17A after deposition of the seed layer over the sidewalls of the trench.

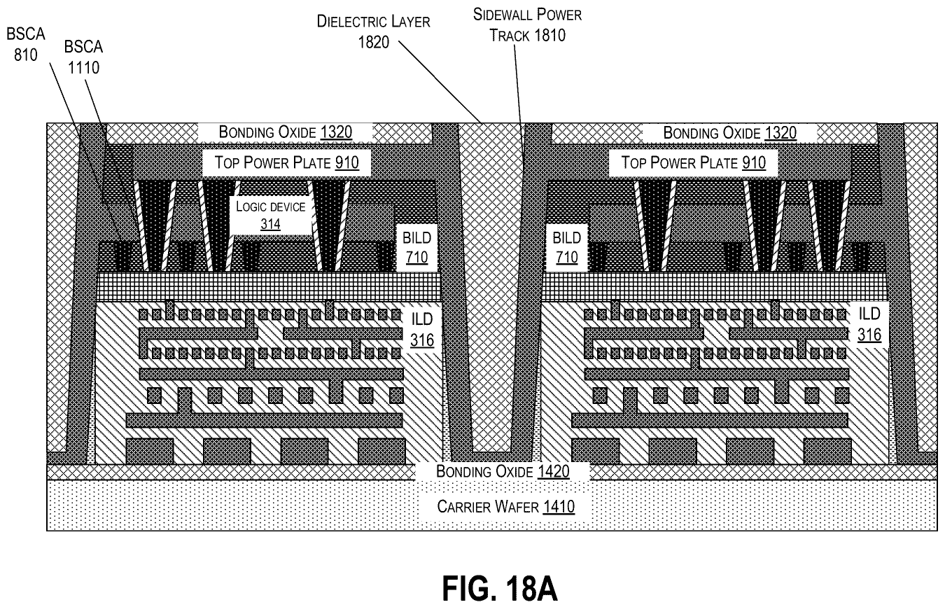

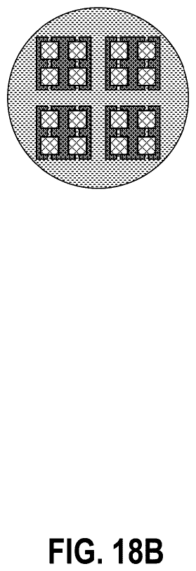

FIG. 18A illustrates the semiconductor device after the growth of the seed layer over the sidewalls of the trench, in accordance with some embodiments. In some embodiments, a preferential copper plating is performed to growth the seed layer over the sidewalls of the trench and form the sidewall power track 1810. Portions of the sidewall power track 1810 can be deposited over the bonding oxide 1420. A dielectric layer 1820 can be formed over the sidewall power track 1810, followed by a planarization step. FIG. 18B illustrates a top view of the semiconductor device shown in FIG. 18A after the growth of the seed layer of the sidewalls of the trench.

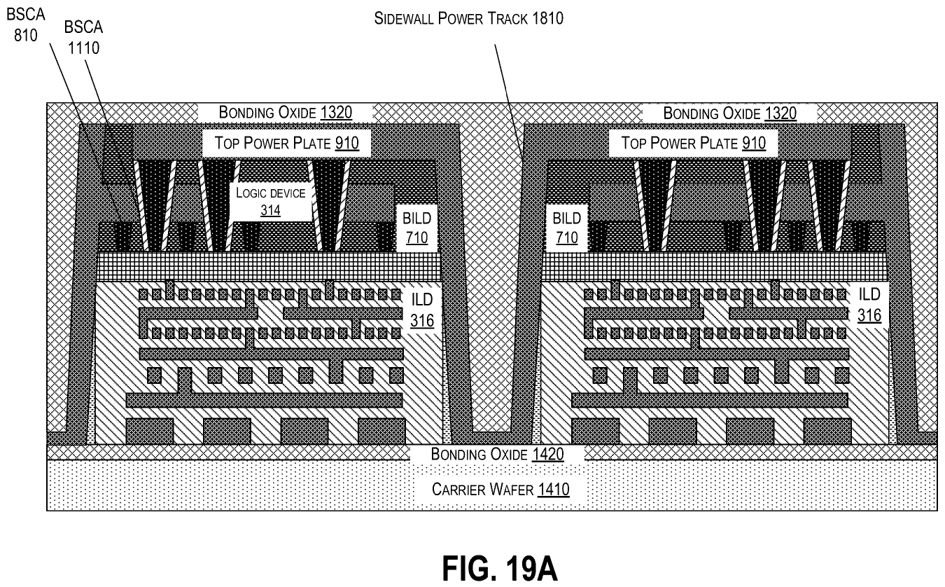

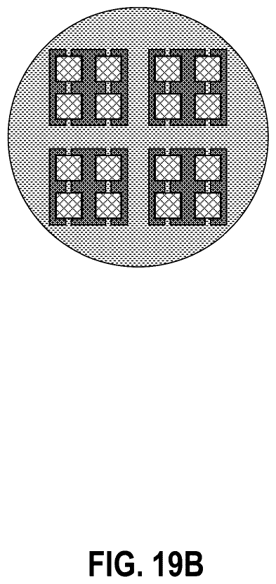

FIG. 19A illustrates the semiconductor device after the recession of exposed copper and cap formation, in accordance with some embodiments. In some embodiments, the excess copper can be removed, i.e., recessed. The recessed portions are filled with the dielectric layer. As a result, the dielectric layer 1820 can form a cap over the semiconductor device. FIG. 19B illustrates a top view of the semiconductor device shown in FIG. 19A after the recession of the exposed copper and the cap formation.

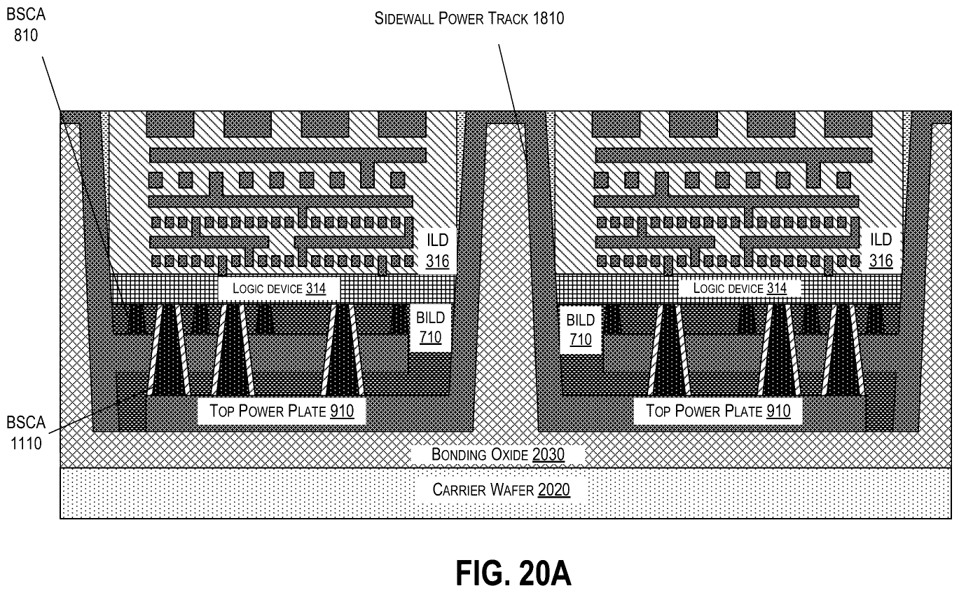

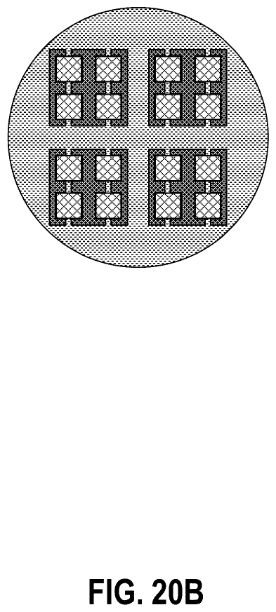

FIG. 20A illustrates the semiconductor device after the wafer flip and carrier wafer bonding, in accordance with some embodiments. In some embodiments, the wafer is flipped, and the carrier wafer 1410 and the bonding oxide 1420 are removed. A carrier wafer 2020 can be bonded to the semiconductor device via a bonding oxide 2023. FIG. 20B illustrates a top view of the semiconductor device shown in FIG. 20A after the formation of the one or more bumps.

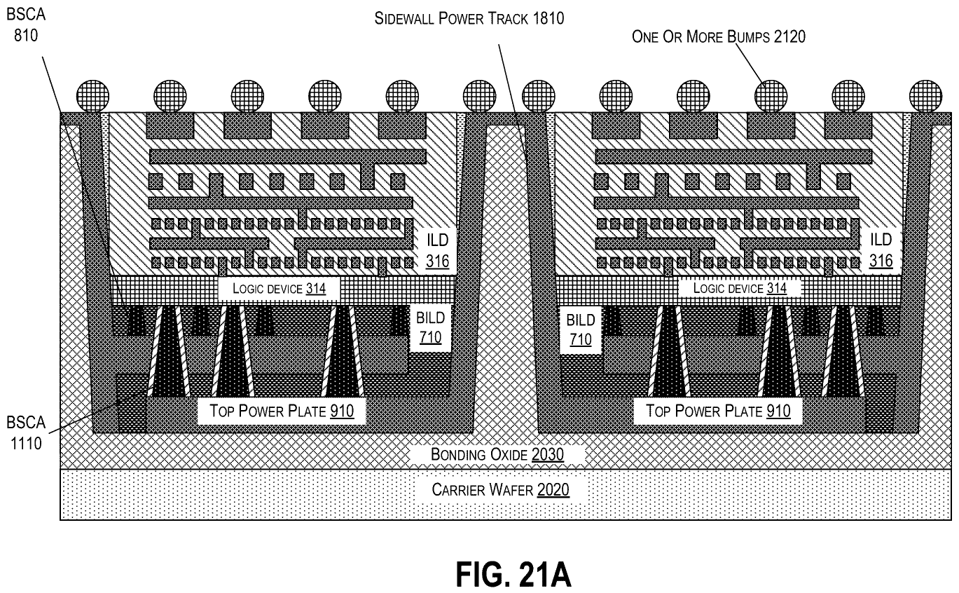

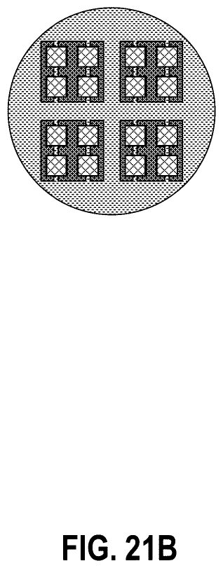

FIG. 21A illustrates the semiconductor device after the formation of the bumps, in accordance with some embodiments. In some embodiments, one or more bumps 2120 are formed over the semiconductor device. FIG. 21B illustrates a top view of the semiconductor device shown in FIG. 21A after the formation of the one or more bumps.

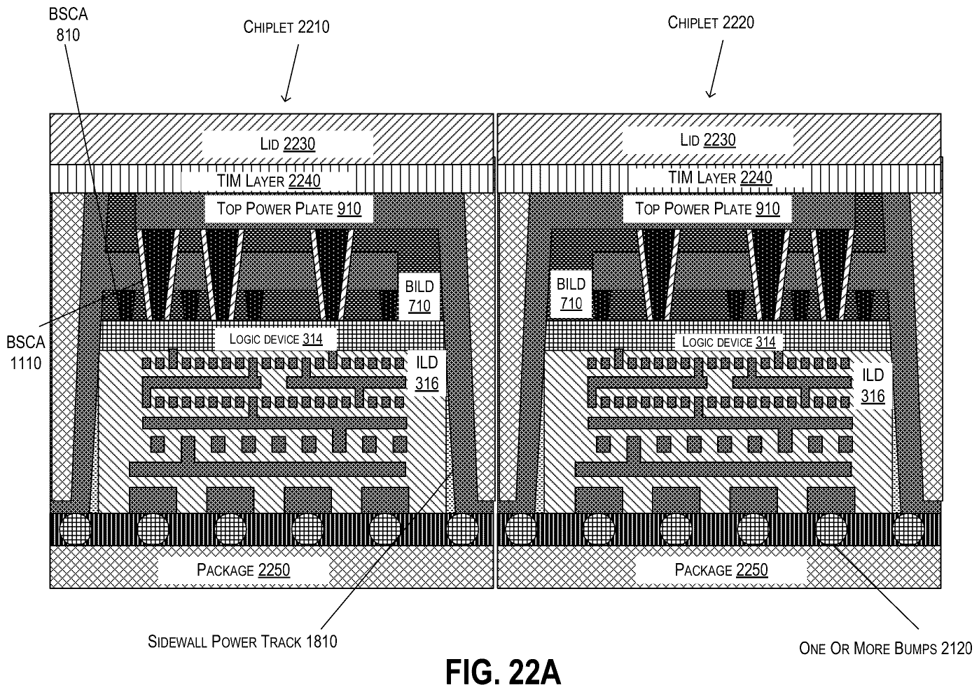

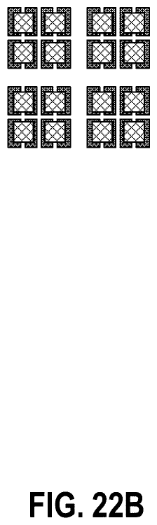

FIG. 22A illustrates the semiconductor device after the carrier wafer de-bonding and dicing the semiconductor device, in accordance with some embodiments. In some embodiments, the carrier wafer 2020 and the bonding oxide 2030 are removed and the semiconductor device is diced into chiplets 2210 and 2220. The chiplets 2210 and 2220 can be attached to a lid 2230 via a TIM layer 2240. The chiplets 2210 and 2220 can be attached to the package 2250 via the one or more bumps 2120. FIG. 22B illustrates a top view of the semiconductor device shown in FIG. 22A after the carrier wafer de-bonding.

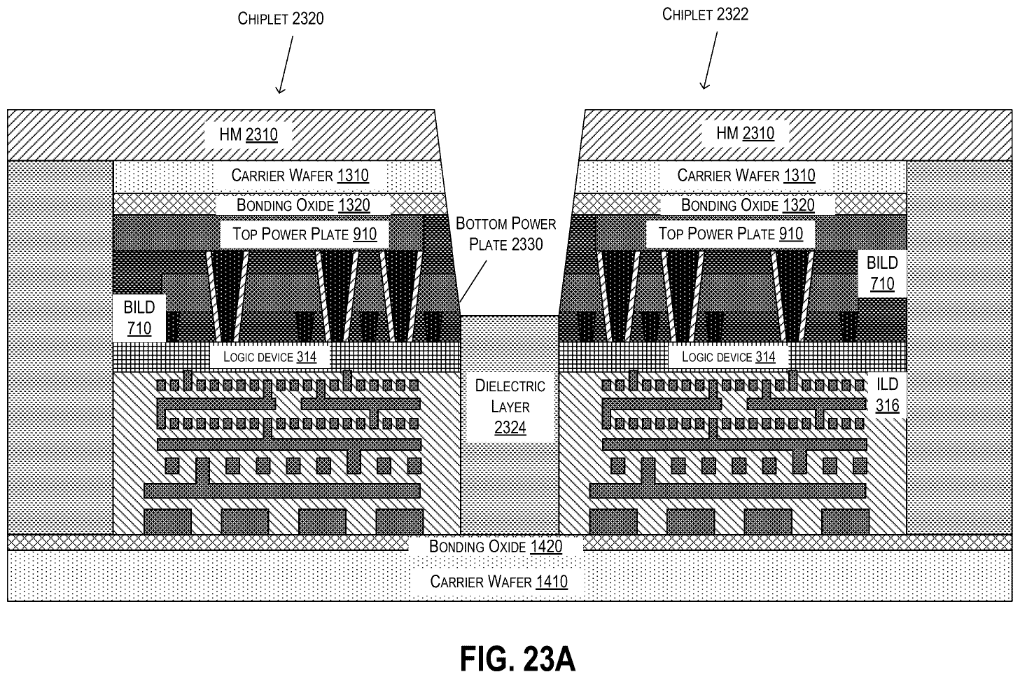

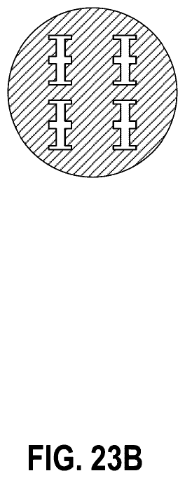

Reference is now made to FIGS. 23-26, which shows the acts of formation of the semiconductor device depicted in FIG. 2A. It should be noted that, the first parts of acts of formation of the semiconductor device as shown in FIG. 2A are similar to the first parts of acts of formation of the semiconductor device as shown in FIG. 1A. Thus, for the sake of simplicity, acts of formation of the semiconductor device shown in FIG. 2A are depicted once the semiconductor device is diced into chiplets.

FIG. 23A illustrates the semiconductor device after the patterning of the sidewall metal trench, in accordance with some embodiments. In some embodiments, a hard mask, HM 2310 is formed over the entire surface of the semiconductor device, while the dielectric layer 2324 remains intact. Portions of the HM 2310 between two adjacent chiplets, chiplet 2320 and chiplet 2322 can be removed until the bottom power plate 2330 is exposed. FIG. 23B illustrates a top view of the semiconductor device shown in FIG. 23A after patterning of the sidewall metal trench.

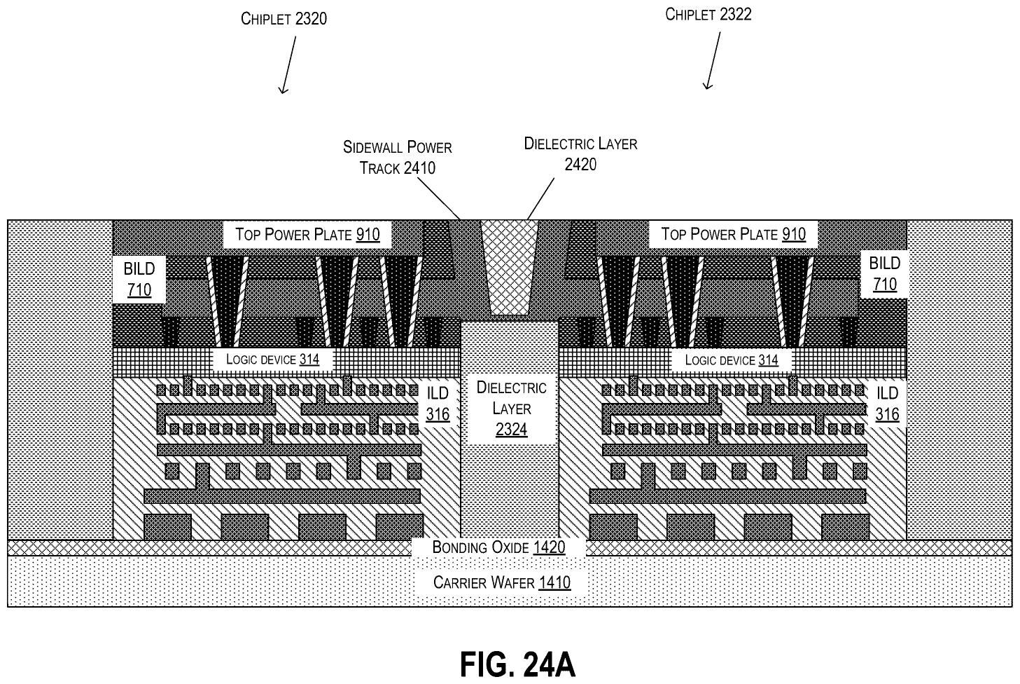

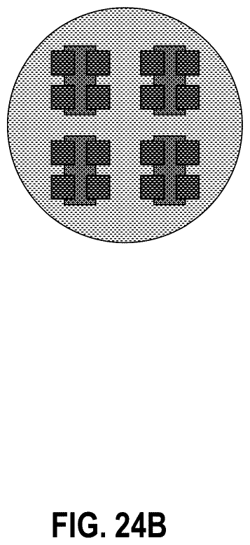

FIG. 24A illustrates the semiconductor device after the deposition of the copper layer over the sidewalls of the trench, in accordance with some embodiments. In some embodiments, the HM 2310 and the bonding oxide 1420 are removed and the carrier wafer is de-bonded. A preferential copper plating is performed to form the sidewall power track 2410 over the sidewalls of the trench. A dielectric layer 2420 can be formed over the sidewall power track 2410, followed by a planarization step. FIG. 24B illustrates a top view of the semiconductor device shown in FIG. 24A after the deposition of the copper layer over the sidewalls of the trench.

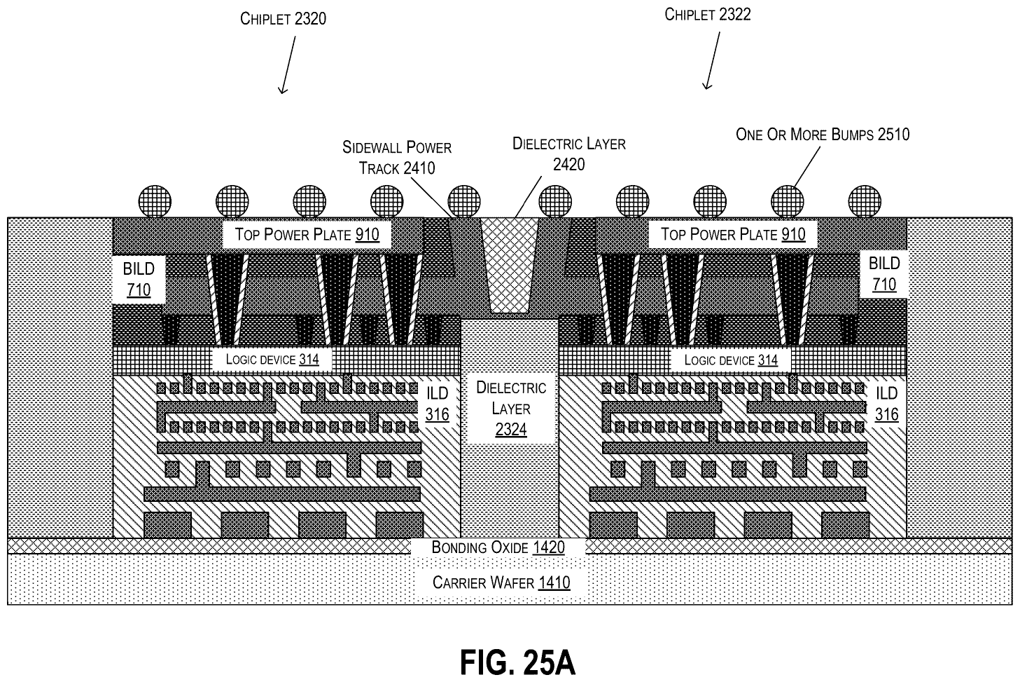

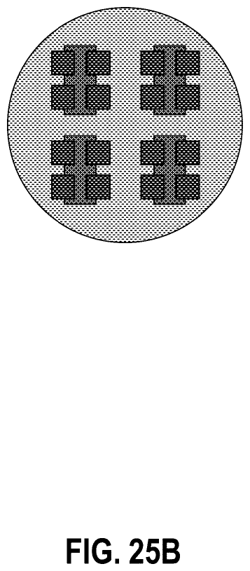

FIG. 25A illustrates the semiconductor device after the formation of the bumps, in accordance with some embodiments. In some embodiments, one or more bumps 2510 are formed over the semiconductor device. FIG. 25B illustrates a top view of the semiconductor device shown in FIG. 25A after the formation of the one or more bumps.

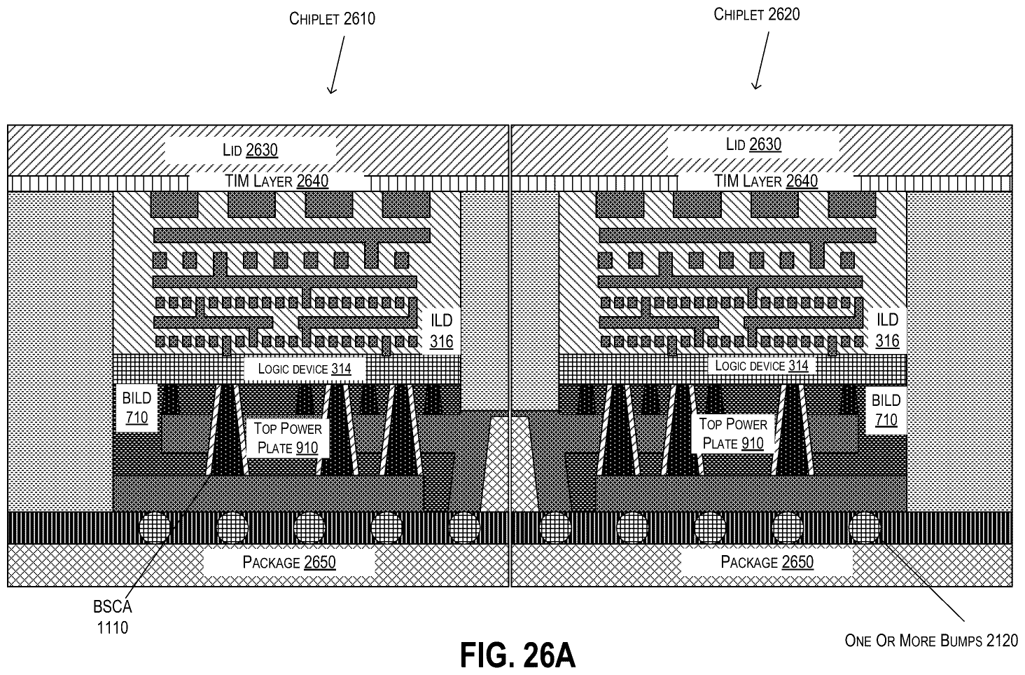

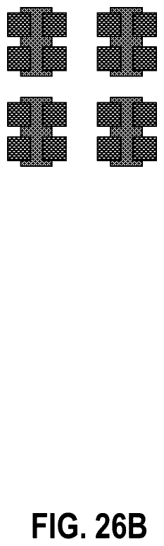

FIG. 26A illustrates the semiconductor device after the carrier wafer de-bonding and dicing the semiconductor device, in accordance with some embodiments. In some embodiments, the carrier wafer and the bonding oxide are removed and the semiconductor device is diced into chiplets 2610 and 2620. The chiplets 2610 and 2620 can be attached to a lid 2630 via a TIM layer 2640. The chiplets 2610 and 2620 can be attached to the package 2650 via the one or more bumps 2510. FIG. 26B illustrates a top view of the semiconductor device shown in FIG. 26A after the carrier wafer de-bonding and dicing the semiconductor device.

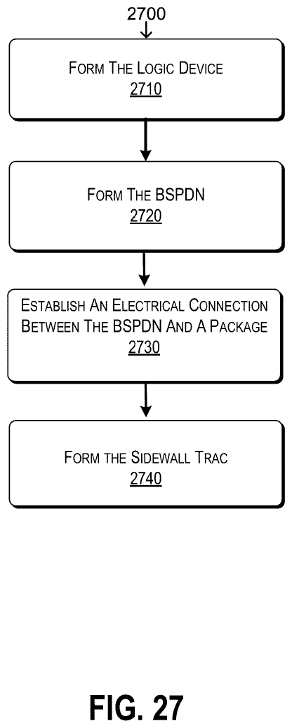

FIG. 27 illustrates a block diagram of a method 2700 for forming the semiconductor device, in accordance with some embodiments. As shown by block 2710, the logic device is formed.

As shown by block 2720, the BSPDN is formed below the logic device.

As shown by block 2730, an electrical connection between the BSPDN and a package coupled to the semiconductor device is established.

As shown by block 2740, the sidewall power track is firmed. The sidewall power track can be extended vertically from a top power plate to the package. The sidewall power track at least partially wraps around a first edge of the semiconductor device.

In one aspect, the method and structures described above may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip may be mounted in a single chip package (such as a plastic carrier, with leads that are affixed to a motherboard or other higher-level carrier) or in a multichip package (such as a ceramic carrier that has either or both surface interconnections or buried interconnections). In any case, the chip can then be integrated with other chips, discrete circuit elements, and/or other signal processing devices as part of either (a) an intermediate product, such as a motherboard, or (b) an end product. The end product can be any product that includes integrated circuit chips, ranging from low-end applications, such as toys, to advanced computer products having a display, a keyboard or other input device, and a central processor.

### CONCLUSION

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications, and variations that fall within the true scope of the present teachings.

The components, steps, features, objects, benefits, and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, the inventive subject matter lies in less than all features of a single disclosed embodiment. Thus, the following claims are hereby incorporated into the Detailed Description, with each claim standing on its own as a separately claimed subject matter.

What is claimed is:

1. A semiconductor device, comprising:
a logic device;
a backside power delivery network (BSPDN); and
a power device electrically connecting the BSPDN to a package coupled to the semiconductor device, wherein the power device comprises:
a bottom power plate extended horizontally above the logic device;
a top power plate extended horizontally above the bottom power plate; and
a sidewall power track extended vertically from the top power plate to the package to electrically connect the BSPDN to the package, wherein portions of the sidewall power track wraps around a first edge of the semiconductor device.

2. The semiconductor device of claim 1, further comprising one or more backside contacts connecting the logic device to the power device.

3. The semiconductor device of claim 2, wherein the sidewall power track is connected to a backside of the logic device through the one or more backside contacts.

4. The semiconductor device of claim 2, wherein at least one backside contact of the one or more backside contacts is isolated from direct contact with the top power plate via an insulation layer.

5. The semiconductor device of claim 1, wherein the logic device further comprises a back end of line (BEOL), wherein the BEOL is connected to the package via one or more bumps.

6. The semiconductor device of claim 5, wherein the logic device is connected to the package via an interconnect layer and the one or more bumps.

7. The semiconductor device of claim 2, wherein the bottom power plate is connected to the package via the one or more backside contacts and one or more bumps.

8. A method for fabrication of a semiconductor device, the method comprising:
forming a logic device;
forming a backside power delivery network (BSPDN) below the logic device; and
establishing an electrical connection between the BSPDN and a package coupled to the semiconductor device via a power device, comprising forming a sidewall power track extended vertically from a top power plate to the package, wherein portions of the sidewall power track wraps around a first edge of the semiconductor device.

9. The method of claim 8, wherein establishing the electrical connection between the BSPDN and the package further comprises:
forming a bottom power plate extended horizontally above the logic device; and
forming the top power plate extended horizontally above the bottom power plate.

10. The method of claim 9, further comprising establishing the electrical connection between the logic device and the power device via one or more backside contacts.

11. The method of claim 10, further comprising connecting the sidewall power track to a backside of the logic device through the one or more backside contacts.

12. The method of claim 10, further comprising isolating at least one backside contact of the one or more backside contacts from direct contact with the top power plate via an insulation layer.

13. The method of claim 9, further comprising:
forming a back end of line (BEOL) within the logic device; and
establishing electrical connections between the BEOL and the package via one or more bumps.

14. A semiconductor device comprising:
a logic device;
a backside power delivery network (BSPDN); and
a power device electrically connecting the BSPDN to a package coupled to the semiconductor device, wherein the power device comprises:
a top power plate extended horizontally below the logic device;
a bottom power plate extended horizontally below the top power plate; and
a sidewall power track extended vertically from the top power plate to the package to electrically connect the BSPDN to the package, wherein portions of the sidewall power track wraps around a first edge of the semiconductor device.

15. The semiconductor device of claim 14, further comprising one or more backside contacts connecting the logic device to the power device.

16. The semiconductor device of claim 15, wherein the sidewall power track is connected to a backside of the logic device through the one or more backside contacts.

17. The semiconductor device of claim 15, wherein at least one backside contact of the one or more backside contacts is isolated from direct contact with the top power plate via an insulation layer.

18. The semiconductor device of claim 14, wherein the logic device further comprises a back end of line (BEOL), wherein the BEOL is connected to the package via one or more bumps.

19. The semiconductor device of claim 18, wherein the top power plate is connected to the package via the sidewall power track and the one or more bumps.

20. The semiconductor device of claim 18, wherein the bottom power plate is connected to the package via the one or more bumps.
